(19) United States
(12) Patent Application Publication
(10) Pub. No.: US 2014/0307371 A1
(43) Pub. Date: Oct. 16, 2014

(54) SUN SHIELD FOR OUTDOOR ELECTRICAL EQUIPMENT

(71) Applicant: Joseph Messner, Chandler, AZ (US)

(72) Inventor: Joseph Messner, Chandler, AZ (US)

(21) Appl. No.: 14/315,262

(22) Filed: Jun. 25, 2014

Related U.S. Application Data
(62) Division of application No. 12/765,822, filed on Apr. 22, 2010, now abandoned.

(51) Int. Cl. H05K 5/03

(52) U.S. Cl. CPC H05K 5/03
USPC 361/679.01

(57) ABSTRACT

A sun shield for shielding outdoor electrical equipment from sunlight is provided. The sun shield comprises a front, the front capable of shielding a front portion of the outdoor electrical equipment; a pair of sides, the pair of sides capable of shielding respective side portions of the outdoor electrical equipment; and a slanted roof, the slanted roof capable of shielding a top portion of the outdoor electrical equipment. Preferably, the slanted roof is provided at an angle such that sunlight is reflected no matter the elevation or azimuth of the sun during the day. The sun shield is placed over a cover of the outdoor electrical equipment leaving an air gap between the sun shield and the cover of the outdoor equipment. Advantageously, the air gap provides for air flow between the sun shield and the cover of the electrical equipment, encouraging heat dissipation. The sun shield is capable of being fastened to the outdoor electrical equipment by attachment to pre-existing screw holes in the cover of the outdoor electrical equipment or bracketing to a wall mount.

### CROSS-REFERENCE TO RELATED APPLICATION

This application is a divisional of U.S. patent application Ser. No. 12/765,822, filed Apr. 22, 2010, which is incorporated herein by reference.

### FIELD OF THE INVENTION

The present invention relates to thermal management of electrical devices and systems.

### BACKGROUND

When solar energy equipment is installed, it is necessary to place outside the building an inverter to convert the direct current (DC) generated by the solar panels to alternate current (AC) used in the business or home. However, an inverter, particularly one installed in a desert climate, can suffer from the effects of excess heat. When electrical equipment overheats, output decreases, and, if this occurs frequently, the overall lifespan of the equipment will be considerably shortened.

Typically, an inverter will have an internal cooling system that includes a heat sink and a fan. The heat sink works by transferring thermal energy from the inverter to the surrounding air which is of a lower temperature. To increase heat dissipation efficiency usually the heat sink will include several fins that increase surface area in contact with the air. To further increase the efficiency, the fan moves hot air away from the equipment. However, even though most inverters work well enough at cooler outdoor temperatures, overheating becomes an issue at higher outdoor temperatures.

### SUMMARY OF THE INVENTION

A sun shield for shielding outdoor electrical equipment from sunlight is provided. The sun shield comprises a front, the front capable of shielding a front portion of the outdoor electrical equipment; a pair of sides, the pair of sides capable of shielding respective side portions of the outdoor electrical equipment; and a slanted roof, the slanted roof capable of shielding a top portion of the outdoor electrical equipment. Preferably, the slanted roof is provided at an angle such that sunlight is reflected no matter the elevation or azimuth of the sun during the day. The sun shield is capable of being fastened to a cover of the outdoor electrical equipment leaving an air gap between the sun shield and the cover of the outdoor equipment. Advantageously, the air gap provides for air flow between the sun shield and the cover of the electrical equipment, encouraging heat dissipation. The sun shield is capable of being fastened to the outdoor electrical equipment by attachment to pre-existing screw holes in the cover of the outdoor electrical equipment or bracketing to a wall mount.

Preferably, the sun shield includes an opening to allow access to operation of the outdoor electrical equipment. Preferably, the opening also includes a visor to protect the opening from sunlight.

Preferably, the sun shield does not cover a back portion of the outdoor electrical equipment, the back portion on an opposite side from the front portion. Preferably, the sun shield also does not cover a bottom portion of the outdoor electrical equipment, the bottom portion on an opposite side from the top portion. Preferably, the sun shield includes air gaps between the sides and the slanted roof. Preferably, each of the front, the pair of sides, and the slanted roof are substantially planar. The pair of sides and the slanted roof are attached to the front.

Preferably, the sun shield is formed by bending a single sheet of substantially flat metal, most preferably, stainless steel. Preferably, the pair of sides each is bent to a predetermined angle relative to the front, the predetermined angle being an acute angle. Preferably, the slanted roof is bent to a predetermined angle relative to the front, the predetermined angle being an acute angle.

These and other aspects, features, and advantages of the present invention will become apparent from the following detailed description of preferred embodiments, which is to be read in connection with the accompanying drawings.

### BRIEF DESCRIPTION OF THE DRAWINGS

FIG. 1 shows an exemplary pair of sun shields installed on outdoor electrical equipment for a home equipped with solar panels, according to a preferred embodiment of the present invention;

FIG. 2 shows a close-up perspective of the exemplary sun shields;

FIG. 3 shows one of the exemplary sun shields in use covering a solar power inverter;

FIG. 4 shows an example of an exemplary sun shield formed from a stainless steel metal plate;

FIG. 5 shows a side view of the exemplary sun shield; and

FIG. 6 shows air flow and light reflection capabilities of an exemplary sun shield.

### DETAILED DESCRIPTION

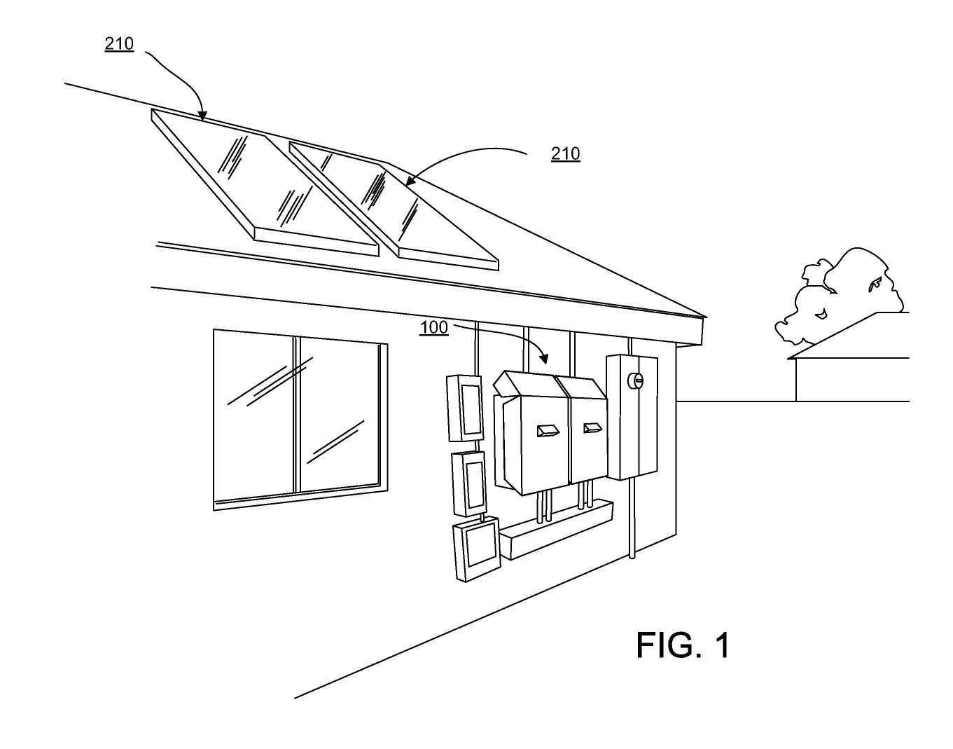

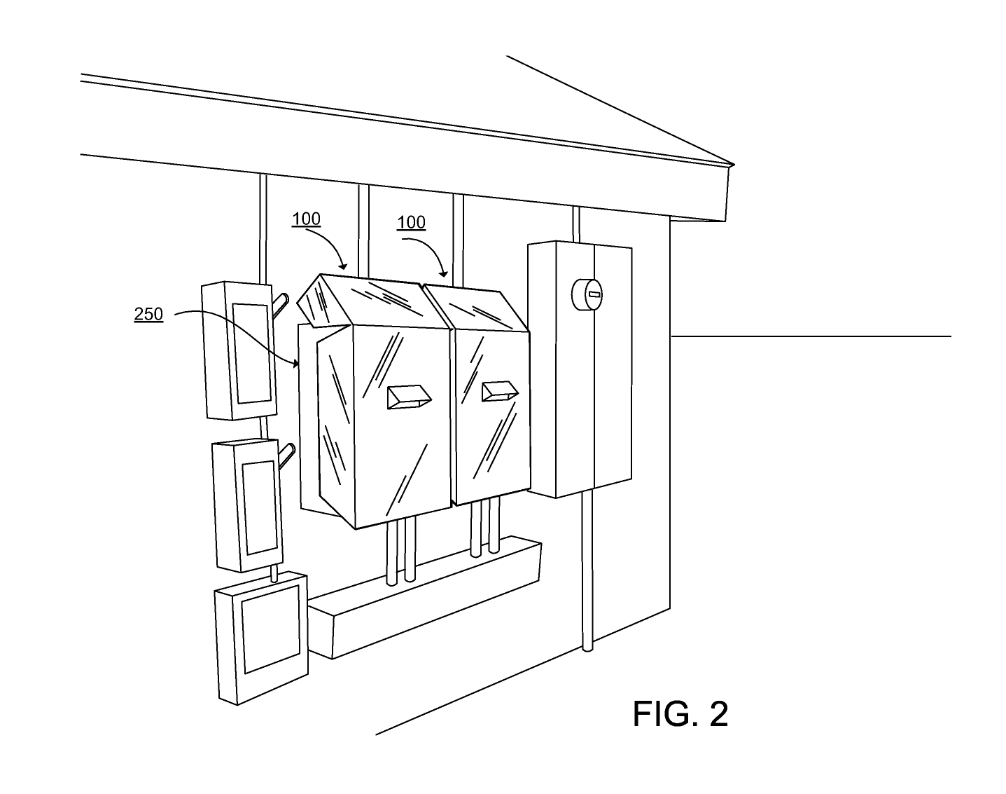

FIG. 1 illustrates an exemplary pair of sun shields 100 installed on outdoor electrical equipment, according to a preferred embodiment of the present invention. FIG. 2 shows a close-up perspective of the sun shields 100. As illustrated, each of the sun shields 100 is installed over a respective solar power inverter used to convert direct current (DC) generated by solar panels 210 to alternating current (AC) used in the home. It is to be understood that various different styles/designs for inverters exist, and that the present invention will be able to accommodate any of these. Further, it is to be appreciated that a sun shield 100 could be used in conjunction with various other types of outdoor electrical equipment. Thus, it is to be understood that the examples described herein are meant to be illustrative, not limiting. Various possible designs for the sun shield 100 exist; the exact dimensions, materials, and structure will depend on such factors as the size and type of the outdoor electrical equipment, costs of the materials and labor, and ornamental considerations.

As will be described in greater detail, the sun shield 100 works by blocking a substantial portion of sunlight exposure and provides a slanted roof for reflecting sunlight no matter the elevation or azimuth of the sun during the day. The sun shield 100 is capable of being placed over a cover of the outdoor electrical equipment leaving an air gap between the sun shield and the cover of the outdoor equipment. Advantageously, the air gap provides for substantial air flow between the sun shield 100 and the cover of the electrical equipment, encouraging heat dissipation.

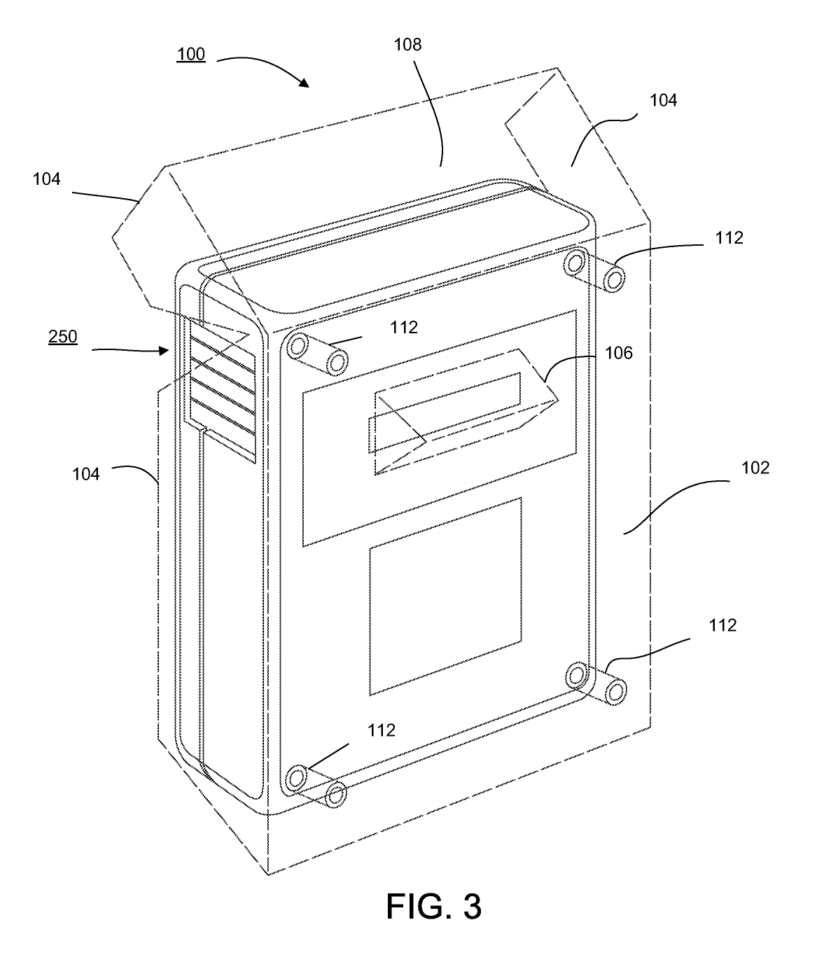

FIG. 3 shows an exemplary sun shield 100 covering a solar power inverter 250. As shown in FIG. 3, the sun shield 100 includes a front 102, the front 102 capable of shielding a front portion of the solar power inverter 250; a pair of sides 104, the pair of sides 104 capable of shielding respective side portions of the solar power inverter 250; and a slanted roof 108, the slanted roof 108 capable of shielding a top portion of the solar power inverter 250. As shown, the sun shield 100 is capable of being fastened to the solar power inverter 250 by attachment of screw post extensions 112 to each of the pre-existing screw holes in the cover of the outdoor electrical equipment. Such screw post extensions 112 feature a screw thread at one end and a threaded hole at the other, and, in this case, allow the sun shield 100 to extend about an inch above the solar power inverter 250, creating an air gap between the sun shield 100 and the cover of the solar power inverter 250, so as to provide efficient heat dissipation. Alternatively, the sun shield could be attached to the outdoor electrical equipment using brackets which extend from the sun shield to respective screw holes in a metal plate affixed to a wall, the metal plate provided by the manufacturer to mount the equipment to the wall. Additionally, the sun shield 100 includes an opening 106 on the front 120 to allow access to operation to a control panel of the outdoor electrical equipment, as shown. Optionally, the opening 106 can also include a visor, as shown. Furthermore, the sun shield 100 may include air gaps between the sides 104 and the slanted roof 108, as shown. However, it is also feasible to construct the sun shield 100 so that the corners between the sides 104 and the front 108 meet, without any air gaps.

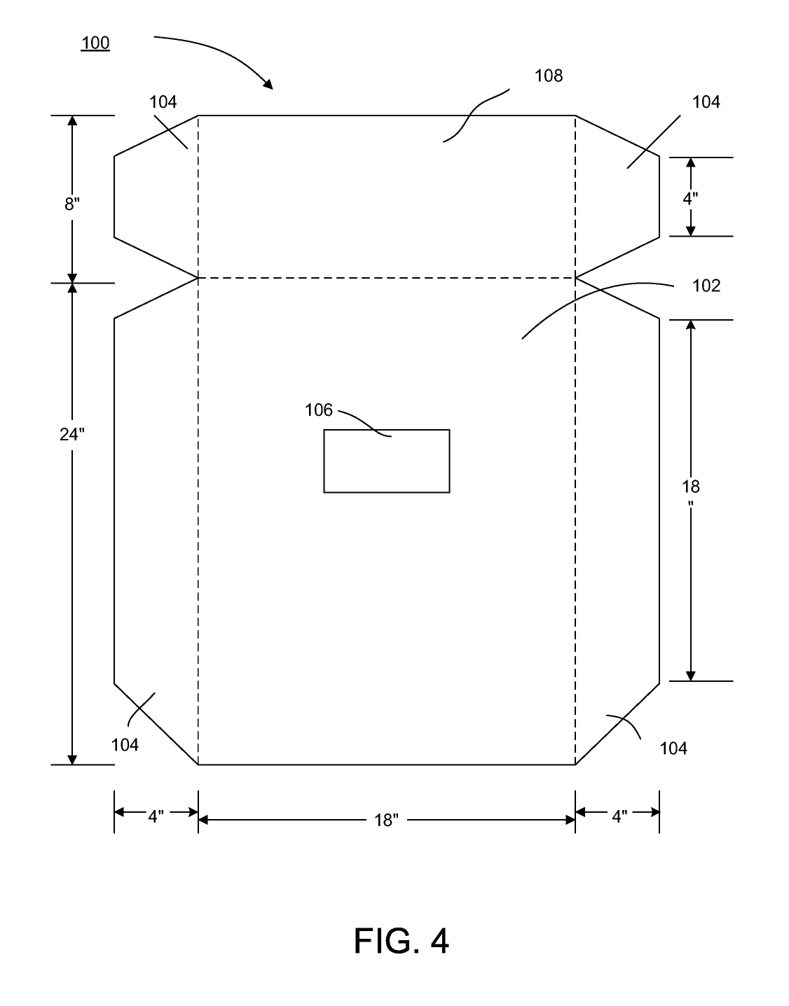

FIG. 4 shows an example of an exemplary sun shield 100 formed from a stainless steel plate. In this example, a substantially planar sheet of stainless steel sheeting measuring is initially cut to the dimensions shown. After cutting the stainless steel plate in accordance with the dimensions shown, the sides 104 are formed by bending the stainless steel sheet along the vertical dotted lines, as shown, to a desired angle (e.g., 30 to 45 degrees). The slanted roof 108 is formed by bending the stainless steel metal plate along the horizontal dotted lines, as shown, to a desired angle (e.g., 30 to 45 degrees). The opening 106 can be formed by cutting a rectangular hole in the portion of the front 102. An optional visor can be added to the opening 106 by instead cutting the opening 106 along all the sides except the top side, and bending along the top side. The sides of the visor are optional and may be formed from scrap portions of the stainless steel plate and then welding it to the opening 106. Although this example involves forming the sun shield 100 by cutting and bending a single sheet of stainless steel, it is to be appreciated that the sun shield 100 may, alternatively, be formed using various other materials and techniques. For example, the sun shield 100 might be instead a molded piece. Additionally, the sun shield 100 could be constructed using aluminum or copper, for example, as well as various nonmetallic materials (e.g., a ceramic material, a heat-resistant plastic).

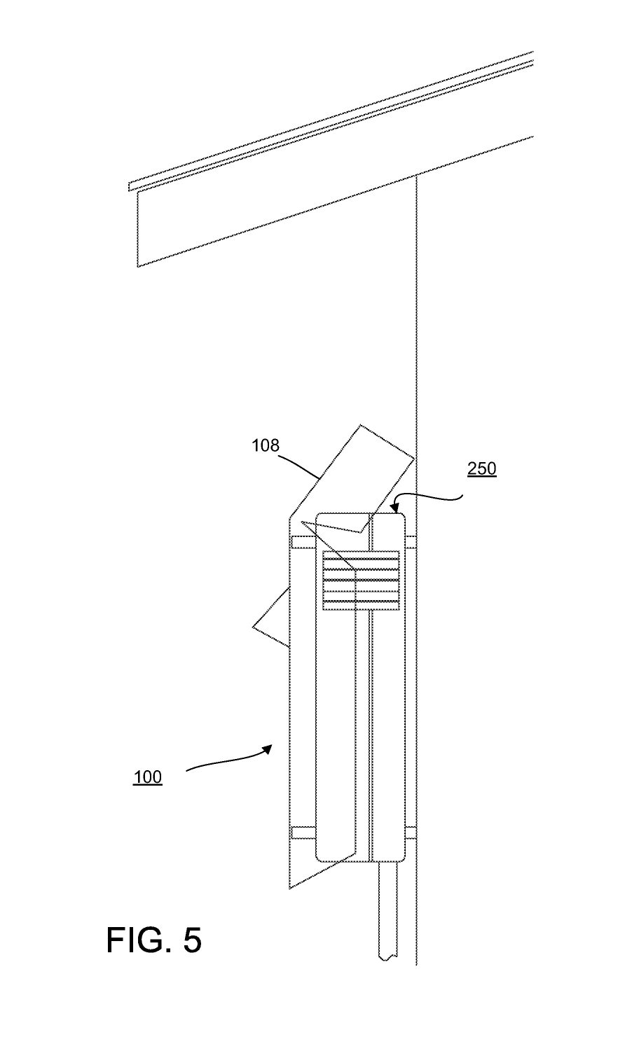

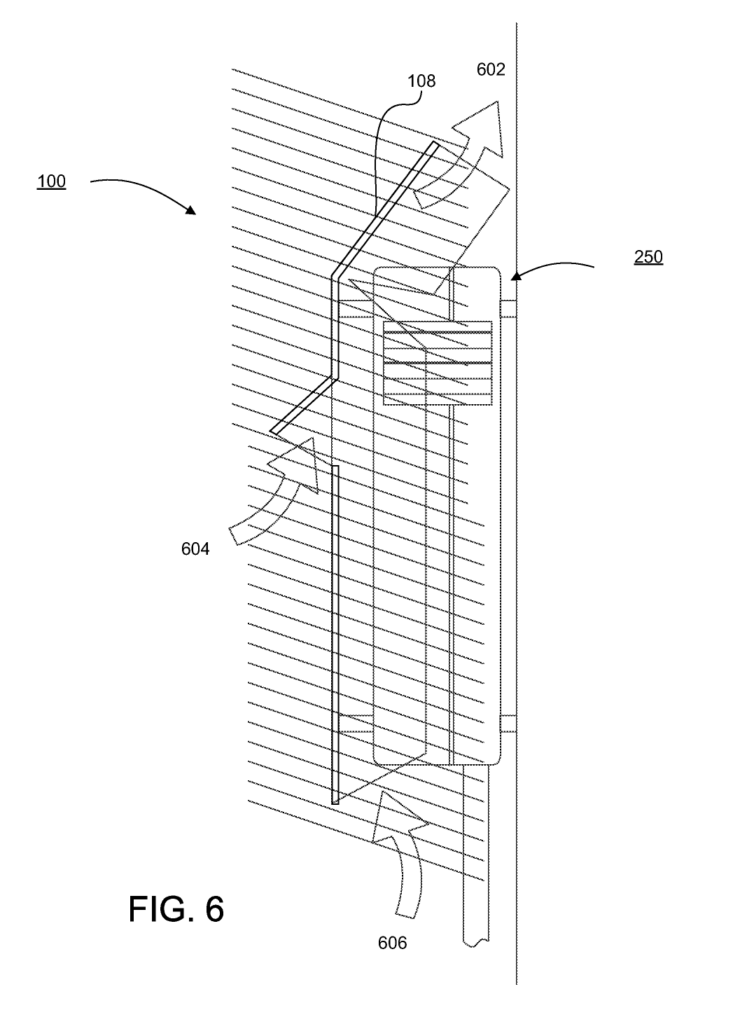

FIG. 5 shows a side view of the exemplary sun shield 100 installed on a house. FIG. 6 shows air flow and light reflection capabilities of this sun shield 100. As shown, the sun shield 100 includes the slanted roof 108 which is set at an angle such that most sunlight is reflected no matter the elevation or azimuth of the sun during the day. Furthermore, because the slanted roof 108 extends several inches above the solar power inverter 250 and an air gap between exists the slanted roof 108 and the solar power inverter 250, much of the heat from the sunlight will not transfer to the solar power inverter 250 (but instead is transferred to the air). Another notable and distinguishing feature of the present invention is that because sun shield 100 is placed loosely atop the cover of the underlying electrical equipment, air flow is greatly facilitated. The air flows into sun shield are depicted by arrows 602, 604, and 606. Because of the novel features of the present invention, heat dissipation efficiency is greatly increased.

While this invention has been described in conjunction with the various exemplary embodiments outlined above, it is evident that many alternatives, modifications and variations will be apparent to those skilled in the art. Accordingly, the exemplary embodiments of the invention, as set forth above, are intended to be illustrative, not limiting. Various changes may be made without departing from the spirit and scope of the invention.

What is claimed is:

1. A sunlight protection system, comprising:
an inverter installed on an outside of a building, the inverter capable of converting direct electrical current from at least one solar panel to alternating current; and
a sun shield attached to a cover of the inverter.

2. The sunlight protection system of claim 1, wherein the sun shield comprises:
a front the structured and arranged to shield a front portion of the inverter;
a pair of slanted sides, the pair of slanted sides structured and arranged to shield respective side portions of the inverter; and
a slanted roof, the slanted roof angle structured and arranged to shield a top portion of the inverter;
wherein the front, the pair of slanted sides and the slanted roof are each substantially planar; and
when mounted to the cover, an air gap of at least one inch exists between the sun shield and the inverter.

3. The sunlight protection system of claim 1, wherein the sun shield does not cover a back portion of the electrical equipment, the back portion on an opposite side from the front portion.

4. The sunlight protection system of claim 1, wherein the sun shield does not cover a bottom portion of the electrical equipment, the bottom portion on an opposite side from the top portion.

5. The sunlight protection system of claim 1, wherein the sun shield is capable of being fastened to a cover of the outdoor electrical equipment leaving the air gap of at least one inch between the sun shield and the cover of the outdoor equipment.

6. The sunlight protection system of claim 1, wherein the sun shield is capable of being fastened to the outdoor electrical equipment by attachment to pre-existing screw holes in the cover of the outdoor electrical equipment.

7. The sunlight protection system of claim 1, wherein the front of the sun shield includes an opening to allow access to operation of the outdoor electrical equipment.

8. The sunlight protection system of of claim 7, wherein the opening includes a visor.

10. The sunlight protection system of claim 1, wherein each of the front, the pair of sides, and the slanted roof are substantially planar.

11. The sunlight protection system of claim 10, wherein the pair of sides and the slanted roof are each attached to the front.

12. The sunlight protection system of claim 1, wherein the sun shield is capable of attachment to the inverter using mounting brackets.

13. The sunlight protection system of claim 1, wherein the sun shield is formed by bending a single sheet of substantially flat metal.

14. The sunlight protection system of claim 13, wherein the pair of sides each are bent to a predetermined angle relative to the front, the predetermined angle being an acute angle greater than 30 degrees.

15. The sunlight protection system of claim 14, wherein the slanted roof is bent to a predetermined angle relative to the front, the predetermined angle being an acute angle.
